(19) United States
(12) Patent Application Publication
(10) Pub. No.: US 2014/0144575 A1
(43) Pub. Date: May 29, 2014

(54) INSULATING LAYER CONDUCTION METHOD

(71) Applicant: SAMSUNG ELECTRO-MECHANICS CO., LTD., Suwon-si (KR)

(72) Inventor: Sung Won JEONG, Suwon-si (KR)

(73) Assignee: SAMSUNG ELECTRO-MECHANICS CO., LTD., Suwon-si (KR)

(21) Appl. No.: 14/091,156

(22) Filed: Nov. 26, 2013

(30) Foreign Application Priority Data
Nov. 27, 2012 (KR) 10-2012-0135348

(51) Int. Cl. H05K 3/00

(52) U.S. Cl. CPC H05K 3/0055
USPC 156/154

(57) ABSTRACT

Disclosed herein is an insulating layer conduction method, and more particularly, an insulating layer conduction method of conducting between the insulating layers through a bump. The method includes providing a hard insulating layer; configuring a land on the hard insulating layer; configuring a bump on the land; laminating a soft insulating layer on the hard insulating layer while being penetrated by the bump; curing the laminated soft insulating layer; and polishing, by a polishing machine, the cured soft insulating layer and an upper surface of the bump.

### CROSS REFERENCE(S) TO RELATED APPLICATIONS

This application claims the benefit under 35 U.S.C. Section 119 of Korean Patent Application Serial No. 10-2012-0135348, entitled “Insulating Layer Conduction Method” filed on Nov. 27, 2012, which is hereby incorporated by reference in its entirety into this application.

### BACKGROUND OF THE INVENTION

1. Technical Field

The present invention relates to an insulating layer conduction method, and more particularly, to an insulating layer conduction method of conducting between insulating layers through a bump.

2. Description of the Related Art

Recently, in accordance with the trend toward miniaturization and multi-functionalization of electronic components, the demand for a fine patterned and highly-integrated thin product has also increased in a printed circuit board which has already been used.

Currently, a method of conducting between layers generally laminated on a multi-layer circuit substrate is to form a hole in an insulating layer using laser drill and then plate an inside of the hole with copper.

An increase in performance of an electronic device means a more rapid response speed. However, in accordance with the increase in the performance of the electronic device, heat generated from the electronic device has continuously increased.

In accordance with the increase in the heat as described above, the substrate becomes deformed and a study for replacing a material of an insulating material with a material having a low thermal expansion coefficient has continuously been conducted in order to solve the deformation problem of the substrate.

In general, in order to decrease the thermal expansion coefficient of the insulating material, content of a filler of the insulating material is increased or content of a glass cloth is increased.

The laser drill processing is to remove the filler or the glass cloth that is a polymer compound of the insulating material and an inorganic material using laser power.

However, in the case in which the content of the filler is increased or the content of the glass cloth is increased, the filler or the glass cloth that is an inorganic material component needed to be removed at the time of forming the hole through the laser drill processing is also increased. Therefore, higher laser power is required or a laser processing time is increased, such that it becomes difficult to conduct the laser processing method and a process cost is increased.

### RELATED ART DOCUMENT

### Patent Document

(Patent Document 1) Korean Patent Laid-Open Publication No. 2009-0114753

### SUMMARY OF THE INVENTION

An object of the present invention is to provide an insulating layer conduction method capable of decreasing the number of processes and increasing reliability of a package substrate by conducting between multi-laminated insulating layers through a bump without using laser.

According to an exemplary embodiment of the present invention, there is provided an insulating layer conduction method, including: providing a hard insulating layer; configuring a land on the hard insulating layer; configuring a bump on the land; laminating a soft insulating layer on the hard insulating layer while being penetrated by the bump; curing the laminated soft insulating layer; and polishing, by a polishing machine, the cured soft insulating layer and an upper surface of the bump.

In the configuring of the bump, a wire may be bonded to the land and may be then forcedly cut.

The bump may have a gourd bottle shape having a diameter of a lower portion thereof wider than that of an upper portion thereof.

The diameter of the upper portion of the bump may be within 20 μm and the diameter of the lower portion may satisfy a range of 25 μm to 35 μm.

The bump may have a pot shape having a diameter of a center portion wider than that of the upper and lower portions.

According to another exemplary embodiment of the present invention, there is provided an insulating layer conduction method, including: providing a hard insulating layer having a core formed therein; configuring a land on each of both ends of the core of the hard insulating layer; configuring a bump on the land; laminating a soft insulating layer on the hard insulating layer while being penetrated by an upper end of the bump; curing the laminated soft insulating layer; and polishing, by a polishing machine, the cured soft insulating layer and the upper end of the bump.

In the configuring of the bump, a wire may be bonded to the land and may be then forcedly cut.

The bump may have a gourd bottle shape having a diameter of a lower portion thereof wider than that of an upper portion thereof.

The diameter of the upper portion of the bump may be within 20 μm and the diameter of the lower portion may satisfy a range of 25 μm to 35 μm.

The bump may have a pot shape having a diameter of a center portion wider than that of the upper and lower portions.

The core may be configured by forming a core hole in the hard insulating layer and filling the core hole with a plating layer. The core hole may be formed through any one of laser processing and mechanical drill processing.

### BRIEF DESCRIPTION OF THE DRAWINGS

FIGS. 1A to 1E are exemplary views showing processes in which an insulating layer is conducted by an insulating layer conduction method according to an exemplary embodiment of the present invention;

FIG. 2 is an exemplary view showing a state in which the insulating layer is conducted by the insulating layer conduction method according to the exemplary embodiment of the present invention;

FIG. 3 is a flow chart showing the process in which the insulating layer is conducted by the insulating layer conduction method according to the exemplary embodiment of the present invention;

FIG. 4 is an exemplary view showing a state in which an insulating layer is laminated on an insulating layer having a core configured therein through the insulating layer conduction method according to the exemplary embodiment of the present invention; and

FIG. 5 is a flow chart showing a process sequence for configuring FIG. 4.

### DESCRIPTION OF THE PREFERRED EMBODIMENTS

Hereinafter, an insulating layer conduction method according to an embodiment of the present invention will be described in detail with reference to the accompanying drawings.

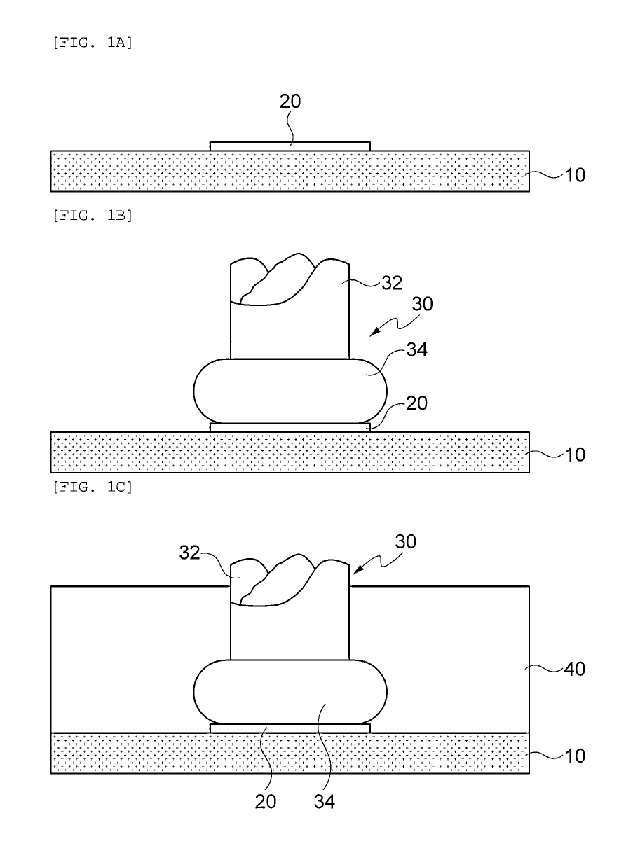

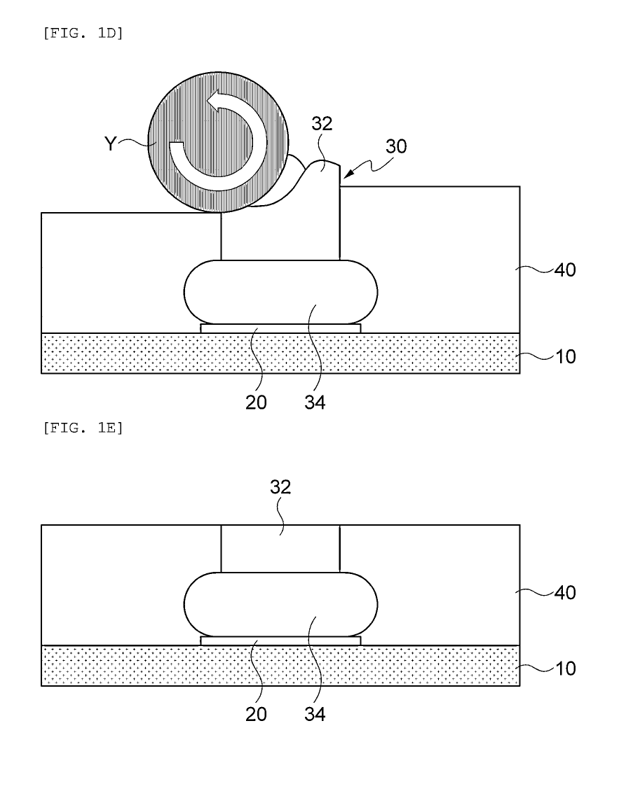

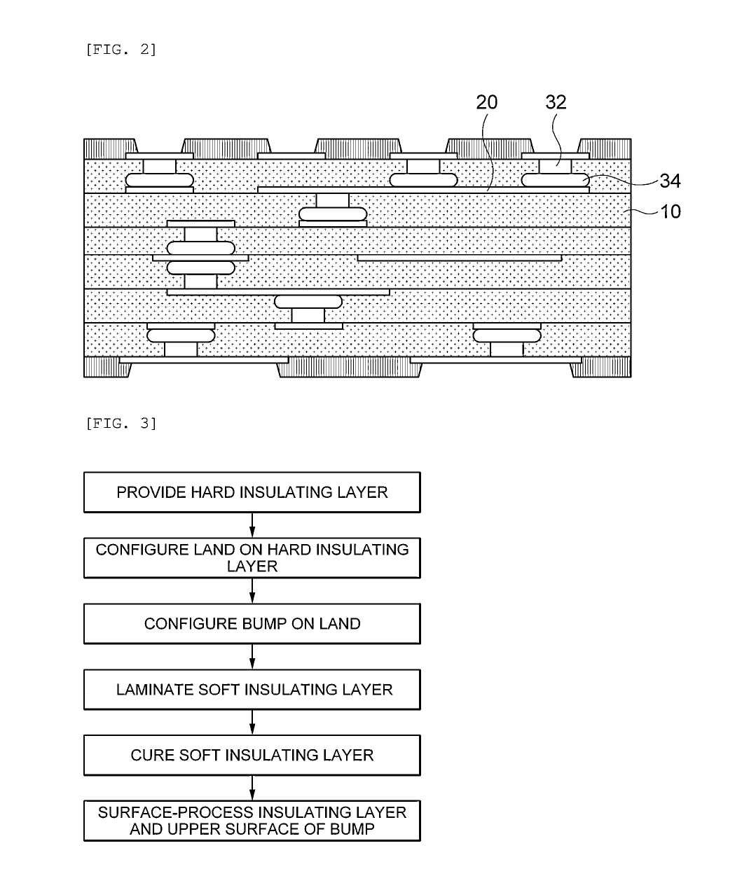

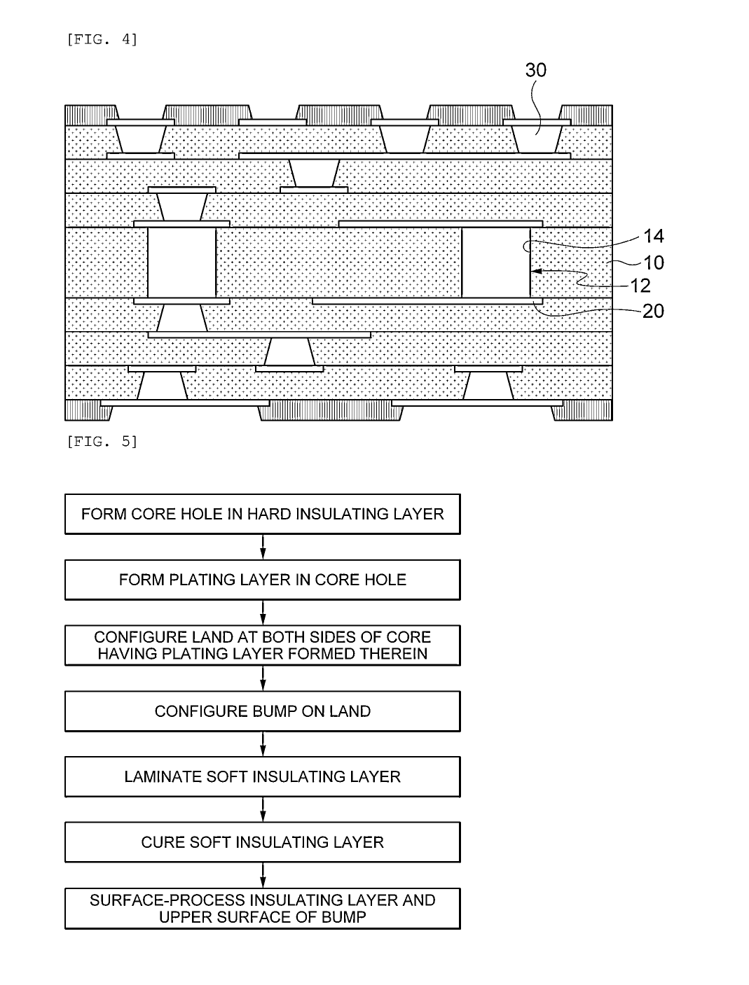

FIGS. 1A to 1E are exemplary views showing processes in which an insulating layer is conducted by an insulating layer conduction method according to an exemplary embodiment of the present invention, FIG. 2 is an exemplary view showing a state in which the insulating layer is conducted by the insulating layer conduction method according to the exemplary embodiment of the present invention, FIG. 3 is a flow chart showing the process in which the insulating layer is conducted by the insulating layer conduction method according to the exemplary embodiment of the present invention, FIG. 4 is an exemplary view showing a state in which an insulating layer is laminated on an insulating layer having a core configured therein through the insulating layer conduction method according to the exemplary embodiment of the present invention, and FIG. 5 is a flow chart showing a process sequence for configuring FIG. 4.

As shown in FIGS. 1 to 3, the insulating layer conduction method according to the exemplary embodiment of the present invention may be applied to both cases in which a soft insulating layer 40 is laminated on both sides based on a hard insulating layer 10 or the soft insulating layer 40 is sequentially laminated on the hard insulating layer 10.

Hereinafter, the insulating layer conduction method according to the exemplary embodiment of the present invention will be described.

When the hard insulating layer 10 is provided, a land 20 is configured on the insulating layer 10. The land 20 may preferably use copper having excellent electrical characteristics and may have different positions depending on a design specification of a circuit pattern.

In the case in which the land 20 is configured on the hard insulating layer 10, a bump 30 is configured on a surface of the land 20. The bump 30, using a wire bonding principle, may be configured by compressing an end of a wire on the surface of the land 20 and forcedly cutting portions having a predetermined length from the compressed end.

The bump 30 configured on the land 20 may have a shape in which diameters of an upper portion 32 and a lower portion 34 of the bump 30 are different. The reason is that a contact area between the surface of the land 20 and the wire becomes wider due to load applied to the end of the wire in a process in which the wire is compressed on the surface of the land 20.

Therefore, the bump 30 may have a gourd bottle shape having the diameter of the lower portion 34 thereof wider than that of the upper portion 32 thereof.

In this case, the diameter of the upper portion 32 of the bump may be within 20 μm and the diameter of the lower portion 34 may satisfy a range of 25 μm to 35 μm.

The diameter of the upper portion 32 of the bump represents a diameter of the wire and may also be changed in the case in which the wire having a larger diameter is used.

In addition, the diameter of the lower portion 34 of the bump may be changed according to a magnitude of the load applied to an upper portion of the land 20.

In other words, the diameter of the lower portion 34 of the bump may become larger, in the case in which the magnitude of the load applied to the surface of the land 20 by the end of the wire is large, conversely, the diameter of the lower portion 34 of the bump may become smaller in the case in which the magnitude of the load is small.

However, in the exemplary embodiment of the present invention, the most preferable shape of the bump 30 may be obtained in the case in which the diameters of the upper portion 32 and the lower portion 34 are within 20 μm and within the range of 25 μm to 35 μm, respectively, in configuring the bump 30.

Therefore, the bump 30 may be configured in the gourd bottle shape, a pot shape (not shown in the drawings), or the like.

In the case in which the bump 30 is configured on the land 20 through the processes as described above, the soft insulating layer 40 is laminated on the hard insulating layer 10.

That is, the soft insulating layer 40 is laminated on the hard insulating layer 10 while being penetrated by the upper portion 32 of the bump.

In this case, a process in which the soft insulating layer 40 is cured may be performed in a state in which the soft insulating layer 40 is not penetrated by the upper portion 32 of the bump in the process in which the soft insulating layer 40 is laminated on the hard insulating layer 10.

In other words, the soft insulating layer 40 may be laminated in the form in which the soft insulating layer 40 is not penetrated by the upper portion 32 of the bump and put on the upper portion 32 of the bump, in the case the upper portion 32 of the bump is not sharp in the process in which the soft insulating layer 40 is laminated on the hard insulating layer 10.

Even in this case, the curing process may be performed in a state in which the soft insulating layer 40 is maintained as it is.

The curing process for the soft insulating layer 40 may be performed using any one of various curing methods such as a thermal curing method, a chemical curing method performed by applying chemicals, an optical curing method performed using light such as ultraviolet (UV).

In the case in which the soft insulating layer 40 is cured through the above-mentioned curing methods, the cured insulating layer and the upper portion 32 of the bump are surface-processed using a polishing machine Y.

In the surface processing, the cured insulating layer and the upper portion 32 of the bump are simultaneously polished so as to make an upper surface of the cured insulating layer flat.

In this configuration, since a height of the upper portion 32 of the bump is very low, the cured insulating layer and the upper portion 32 of the bump are simultaneously removed through the surface-processing and the cured insulating layer is then compressed, thereby closely adhering the soft insulating layer 40 put on the upper portion 32 of the bump to the soft insulating layer 10.

When the surface processing as described above is finished, processes in which the land 20 is configured on the cured insulating layer, the bump 30 is configured on the land 20, and the surface processing is performed are repeatedly performed.

Therefore, in the case in which the insulating layer conduction method according to the exemplary embodiment of the present invention is performed, process forming a via hole or forming a seed layer and a plating layer in the via hole using laser or a drill in order to conduct between the layers may be omitted, thereby making it possible to improve productivity by decreasing the amount of working processes.

Meanwhile, the insulating layer conduction method according to the exemplary embodiment of the present invention may be applied to a form in which the soft insulating layer 40 is laminated based on the hard insulating layer 10 having the core 12 configured therein as shown in FIGS. 4 and 5.

The hard insulating layer 10 having the core 12 configured therein first forms a core hole 14 using the laser or the drill in order to configure the core 12 in the hard insulating layer 10.

The core hole 14 may have a position thereof determined according to the design of the circuit pattern and may be vertically penetrated.

An inner portion of the core hole 14 is plated to form a plating layer. After forming of the plating layer in the inner portion of the core hole 14, surface processing of the upper portion and the lower portion of the hard insulating layer 10 may be performed.

In this case, the core 12 may be configured so as to have a height of about 0.2 to 0.4 mm. This height may be changed according to a thickness of the hard insulating layer 10.

In the case in which the core 12 is configured in the hard insulating layer 10 as described above, the land 20 may be configured at both sides of the core 12. Here, in the case of the land 20 configured on the core 12, the processing is not simultaneously performed at both sides of the core 12, but is first performed at any one side of the core 12 and then performed at the other side thereof.

The land 20 may be configured to have the diameter wider than that of the core 12. The land 20 may be made of the same metal as the core 12 so as to electrically conduct with the core.

After configuring the land 20 at both sides of the core 12, the bump 30 is configured on the land 20 through the processes as described above and the soft insulating layer 40 is laminated on the hard insulating layer 10.

Next, the processes in which the soft insulating layer 40 is cured and then surface-processed are repeatedly performed, thereby making it possible to laminate a plurality of insulating layers 40.

As described above, the insulating layer conduction method according to the exemplary embodiment of the present invention may allow conduction of the insulating layer by using the bump in both cases in which the core is configured in the insulating layer or the core is not configured in the insulating layer.

The insulating layer conduction method according to the exemplary embodiment of the present invention may decrease the number of processes and increase reliability of a package substrate by conducting between multi-laminated insulating layers through a bump without using laser.

Although the insulating layer conduction method according to the exemplary embodiment of the present invention has been described, the present invention is not limited thereto, but those skilled in the art will appreciate that various applications and modifications are possible.

What is claimed is:

1. An insulating layer conduction method, comprising:
providing a hard insulating layer;
configuring a land on the hard insulating layer;
configuring a bump on the land;
laminating a soft insulating layer on the hard insulating layer while being penetrated by the bump;
curing the laminated soft insulating layer; and
polishing, by a polishing machine, the cured soft insulating layer and an upper surface of the bump.

2. The method according to claim 1, wherein in the configuring of the bump, a wire is bonded to the land and is then forcedly cut.

3. The method according to claim 1, wherein the bump has a gourd bottle shape having a diameter of a lower portion thereof wider than that of an upper portion thereof.

4. The method according to claim 3, wherein the diameter of the upper portion of the bump is within 20 μm and the diameter of the lower portion satisfies a range of 25 μm to 35 μm.

5. The method according to claim 1, wherein the bump has a pot shape having a diameter of a center portion wider than that of the upper and lower portions.

6. An insulating layer conduction method, comprising:
providing a hard insulating layer having a core formed therein;
configuring a land on each of both ends of the core of the hard insulating layer;
configuring a bump on the land;
laminating a soft insulating layer on the hard insulating layer while being penetrated by an upper end of the bump;
curing the laminated soft insulating layer; and
polishing, by a polishing machine, the cured soft insulating layer and the upper end of the bump.

7. The method according to claim 6, wherein in the configuring of the bump, a wire is bonded to the land and is then forcedly cut.

8. The method according to claim 6, wherein the bump has a gourd bottle shape having a diameter of a lower portion thereof wider than that of an upper portion thereof.

9. The method according to claim 8, wherein the diameter of the upper portion of the bump is within 20 μm and the diameter of the lower portion satisfies a range of 25 μm to 35 μm.

10. The method according to claim 6, wherein the bump has a pot shape having a diameter of a center portion wider than that of the upper and lower portions.

11. The method according to claim 6, wherein the core is configured by forming a core hole in the hard insulating layer and filling the core hole with a plating layer.

12. The method according to claim 11, wherein the core hole is formed through any one of laser processing and mechanical drill processing.
